(19) United States
(12) Patent Application Publication
(10) Pub. No.: US 2025/0380523 A1
(43) Pub. Date: Dec. 11, 2025

(54) BACKSIDE DEEP TRENCH ISOLATION WITH NEGATIVE BIAS

(71) Applicant: Taiwan Semiconductor Manufacturing Company, Ltd., Hsinchu (TW)

(72) Inventors: Ming-Tsong Wang, Taipei City (TW); Chih-Lung Cheng, Tainan City (TW); Jen-Cheng Liu, Hsin-Chu City (TW)

(21) Appl. No.: 18/739,416

(22) Filed: Jun. 11, 2024

(51) Int. Cl. H01L 27/146; H01L 23/522

(52) U.S. Cl. CPC H10F 39/807; H01L 23/5225; H10F 39/011; H10F 39/811

(57) ABSTRACT

Some embodiments relate to an integrated device including: a first substrate having a first side and a second side; a pixel array on the first side of the first substrate; a deep trench isolation (DTI) structure surrounding photodiodes of the pixel array, the DTI structure comprising an insulative barrier layer surrounding a conductive core; an interconnect structure on the second side of the first substrate; a conductive pad level with the second side of the first substrate coupled to the interconnect structure; and a first connector coupling the conductive pad to the conductive core of the DTI structure and extending across the first side of the first substrate.

### BACKGROUND

In some applications, such as the photodiodes in pixel circuits, some embodiments isolate of the photodiodes using deep trench isolation (DTI) structures, which uses at least one etching step to form trenches before filling them with an isolating barrier. The etching step, however, damages the surface of the remaining portions of the underlying substrate. This damage may result in leakage currents or white noise in the integrated circuit, leading to a loss in performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B illustrate a cross-sectional view and a top down view of some embodiments of a DTI structure with a negatively biased conductive core.

FIG. 2 illustrates a cross-sectional view of some embodiments of a DTI structure with a negatively biased conductive core, where a first connector directly contacts the conductive core beneath a buried color filter array (BCFA).

FIG. 3 illustrates a cross-sectional view of some embodiments of a DTI structure with a negatively biased conductive core, where the first connector contacts a periphery structure that is electrically coupled to the conductive core.

FIG. 4 illustrates a cross-sectional view of some embodiments of a DTI structure with a negatively biased conductive core, where the first connector contacts a periphery structure that is electrically coupled to the conductive core and where the pixel array is in a BCFA configuration.

FIGS. 5A-5B illustrate top down views of some embodiments of a pixel array surrounded by a conductive shield, where the first connector contacts a grid structure above the DTI structure.

FIGS. 6A-6B illustrate cross-sectional views of some embodiments of a DTI structure with a negatively biased conductive core, where the grid directly contacts the conductive core of the DTI structure.

FIG. 7 illustrates a cross-sectional view of a DTI structure with a conductive core before the formation of the grid or the first connector.

FIGS. 8-24 illustrate a series of cross-sectional views of some embodiments of a method of forming a DTI structure with a negatively biased conductive core.

FIGS. 25-28 illustrate a series of cross-sectional views of some embodiments of a method of forming a DTI structure with a negatively biased conductive core where the pixel array is in a BCFA configuration.

FIG. 29 illustrates a flowchart of some embodiments of a method of forming a DTI structure with a negatively biased conductive core.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A pixel array comprises a plurality of photodiodes surrounded by a deep trench isolation (DTI) structure. The DTI structure extends in a grid pattern around the plurality of photodiodes, separating the photodiodes from one another and isolating them to mitigate the amount of interference that may occur between the photodiodes. In some embodiments, the DTI structures have an insulative barrier layer surrounding a core fill. The core fill may be polysilicon, an insulative material, or the like. The insulative barrier layer results in greatly reducing the number of electrons that may pass from one photodiode to other photodiodes in the pixel array. However, the etching process that is used to form the DTI structure damages the inner sidewalls of the substrate surrounding the DTI structure. The damage caused to the inner sidewalls of the substrate may comprise point defects, dangling bonds, or residue left behind on the sidewalls after the etching process, leading to further defects in the substrate. The damage may be mitigated by reducing the depth or altering the critical dimension of the DTI etch, which compromises the effectiveness of the DTI structure in isolating the photodiodes.

The damage at or near the DTI structure results in dark current, or white noise, in the photodiodes of the pixel array. The photodiodes generate a signal when light enters the photodiode, as the energy from the photons energize electrons and generate a current. The dark current alters the generated signal from the photodiode, leading to noise in the detected signal and a loss of performance of the pixel array. Therefore, a DTI structure that may mitigate dark current resulting from etching damage at the inner sidewalls of the substrate without introducing additional masking layers to the pixel array is desirable.

The present disclosure provides for a DTI structure that comprises a conductive core surrounded by an insulative barrier layer. The conductive core is coupled to a first connector, that in turn is coupled to a level shift circuit in an underlying interconnect structure. The level shift circuit applies a negative bias to the first connector, resulting in the conductive core of the DTI structure being negatively biased. The negative bias of the DTI structure attracts holes (positively charged carriers) to the portions of the substrate surrounding the DTI structures. The attracted holes form a depletion region surrounding the DTI structure and coinciding with the damaged inner sidewalls of the substrate. Stray electrons from the damaged inner sidewalls combine with the attracted holes to remove the electrons before they escape into the photodiodes. Further, the negative bias in the conductive core repels electrons from the photodiode, preventing them from interacting with the damaged sidewalls. The depletion region isolates the plurality of photodiodes from the damaged sidewalls, resulting in a reduction of white noise and an increase in performance in the device. Further, the improvements to the performance and reduction in white noise may result in a greater range of depths and critical dimensions the DTI structure may have, further improving the isolation of the photodiodes. In some embodiments, the first connector is a wire and is formed in a same layer as wires coupling to substrate grounding structure around a periphery of the pixel array, resulting in no additional wire layers being used to add a bias to the conductive core of the DTI structure.

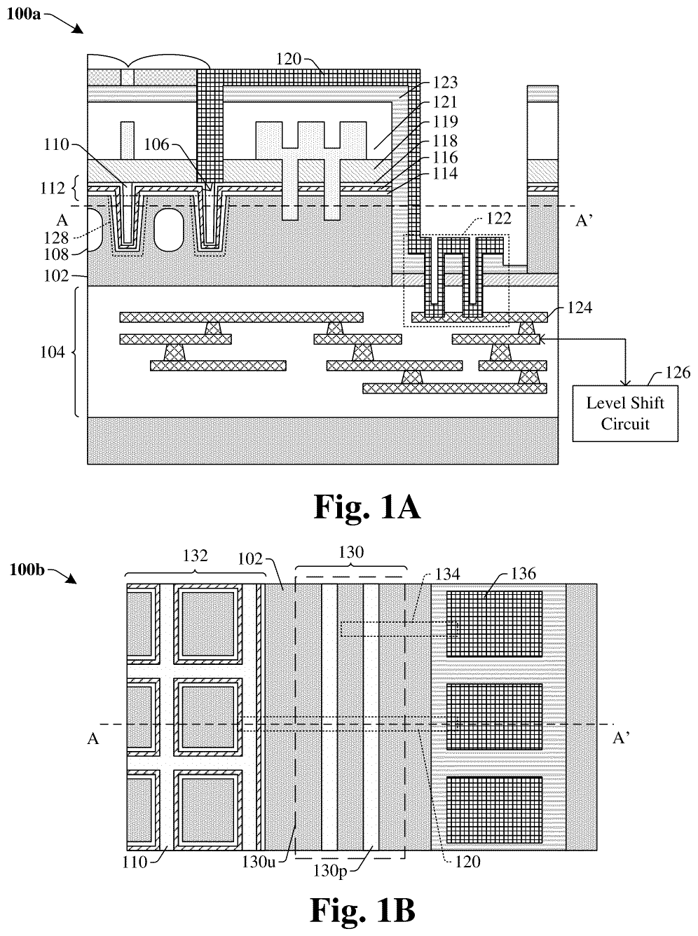

FIGS. 1A and 1B illustrate a cross-sectional view 100a and a top down view 100b of some embodiments of a DTI structure with a negatively biased conductive core. The cross-sectional view 100a of FIG. 1A is taken along the line A-A′ of FIG. 1B.

As shown in the cross-sectional view 100a of FIG. 1A, a first substrate 102 having a first surface 102a and a second surface 102b overlies an interconnect structure 104. A DTI structure 106 surrounds a plurality of photodiodes 108. The DTI structure comprises a conductive core 110 and an insulative barrier layer 112, and extends in a grid pattern, isolating the plurality of photodiodes from each other. In some embodiments, the insulative barrier layer 112 comprises a first insulative layer 114, a second insulative layer 116, and a third insulative layer 118. In some embodiments, the first insulative layer 114 is or comprises a high-k material such as hafnium dioxide (HfO₂), tantalum pentoxide (Ta₂O₅), or the like. In some embodiments, the second insulative layer 116 is or comprises a high-k material that is different from the material of the first insulative layer 114. In some embodiments, the third insulative layer 118 is or comprises an oxide such as silicon dioxide, or the like. In some embodiments, the insulative barrier layer 112 is a bottom-layer anti reflective coating (BARC).

A first connector 120 is coupled to the conductive core 110 of the DTI structure 106. The first connector 120 extends over the first surface 102a of the first substrate 102 to a first conductive pad 122. A first interlayer dielectric 119, a second interlayer dielectric 121, and a third interlayer dielectric 123 space the first connector 120 from the first surface 102a of the first substrate 102. The first conductive pad 122 extends into the underlying interconnect structure 104 and couples to a first connector layer 124 of the interconnect structure 104. The interconnect structure 104 couples the first conductive pad 122 to a level shift circuit 126. During operation, the level shift circuit 126 is configured to bias the first conductive pad with a first negative voltage. In some embodiments, the first negative voltage may be, for example, between −0.5 and −1.5 volts, −1 and −2 volts, −0.2 and −1.2 volts, or the like. The first negative voltage biases the conductive core 110 of the DTI structure 106, resulting in a depletion region 128 forming within the first substrate 102 around the conductive core 110. The depletion region 128 comprises a greater number of positively charged carriers (e.g., holes) than negatively charged carriers (e.g., electrons) due to the positively charged carriers being attracted to the negatively biased conductive core 110. Electrons that form the dark current that may result from the damaged surface of the inner sidewalls of the first substrate 102 combining with the holes in the depletion region 128 instead of traveling further into the pixel array, thereby mitigating the dark current and isolating the damaged surface of the first substrate 102 from the pixel array. Further, the enhanced isolation of the damaged surface from the pixel array extends the amount of damage the inner sidewalls of the first substrate 102 may sustain before reaching an amount of dark current comparable to embodiments that do not utilizing a biased conductive core.

As shown in the top down view 100b of FIG. 1B, in some embodiments, there is a substrate grounding structure 130 that extends into the first substrate 102 at a periphery of the pixel array 132. The substrate grounding structure 130 has an upper portion 130u (shown in phantom) and a plurality of prongs 130p that extend into the first substrate 102. The plurality of prongs 130p ground the first substrate 102 (e.g., bias the first substrate 102 to 0 volts). In some embodiments, a second connector 134 extends from a second pad 136 and is coupled to the substrate grounding structure 130. In further embodiments, the second pad is biased by a ground line to 0 volts. The substrate grounding structure 130 mitigates the effect other circuit components on the first substrate 102 may have on the pixel array 132 and grounds the first substrate 102 such that the first negative voltage is measurably different than the voltage of the first substrate 102. In embodiments with a second connector 134, the first connector 120 extends over the substrate grounding structure 130 and is coupled directly to the conductive core 110.

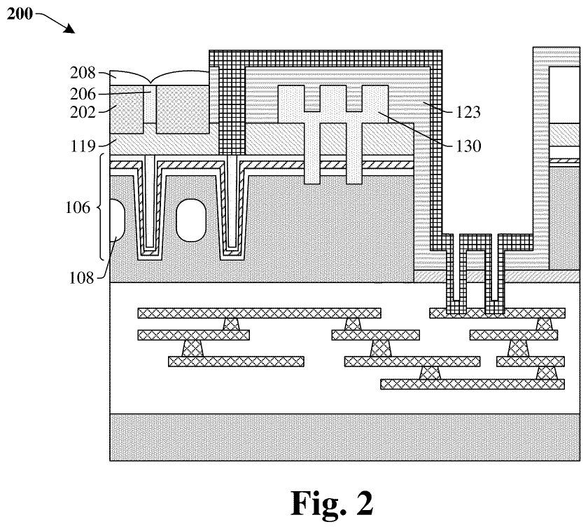

FIG. 2 illustrates a cross-sectional view 200 of some embodiments of a DTI structure with a negatively biased conductive core, where a first connector directly contacts the conductive core beneath a buried color filter array (BCFA).

A plurality of color filters 202 overly the DTI structure 106 and the plurality of photodiodes 108. The plurality of photodiodes 108 are arrayed in a first grid pattern across the pixel array, and the plurality of color filters 202 are arrayed in a same grid pattern as the first grid pattern, directly above the plurality of photodiodes 108. In some embodiments, the plurality of color filters 202 are positioned above the third interlayer dielectric 123 that overlies the substrate grounding structure 130 and a grid 206 overlying the DTI structure 106. In other embodiments, the plurality of color filters 202 are level with the grid 206 and are separated by segments of the grid 206 from each other. In further embodiments, the plurality of color filters 202 extend beneath the grid 206 into the first interlayer dielectric 119. The second interlayer dielectric (see 121 of FIG. 1A) is omitted in some embodiments where the plurality of color filters 202 are level with the grid 206. A plurality of lenses 208 are positioned above the plurality of color filters 202 and are arrayed across the first substrate 102 in a same pattern as the first pattern.

The grid 206 extends in a grid pattern directly above the DTI structure 106. In some embodiments, the grid 206 is or comprises a conductive material, such as a metal or the like. The DTI structure 106 comprises a plurality of segments, and the grid 206 comprises a plurality of segments overlying the segments of the DTI structure 106. In some embodiments, the grid 206 is level with the substrate grounding structure 130. In further embodiments, the grid 206 is coupled to and biased to the same voltage as the substrate grounding structure 130. In other embodiments, the grid 206 is coupled to and biased to the same voltage as the DTI structure 106. In some embodiments, the grid 206 and the substrate grounding structure 130 are or comprise a same material and are level with one another in a grid layer.

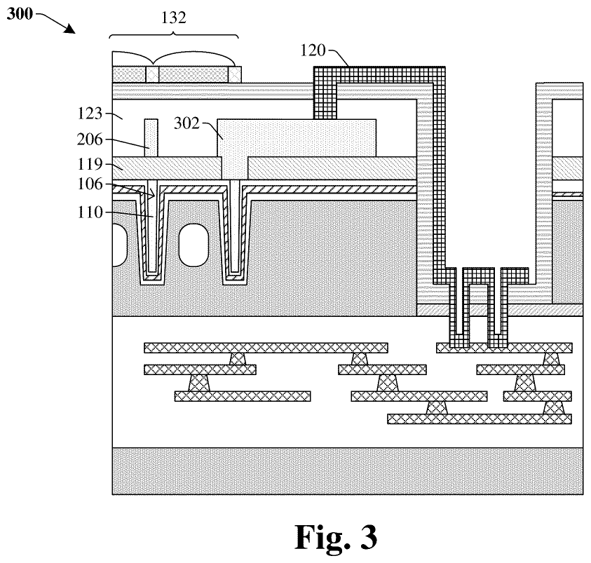

FIG. 3 illustrates a cross-sectional view 300 of some embodiments of a DTI structure with a negatively biased conductive core, where the first connector contacts a periphery structure that is electrically coupled to the conductive core.

In some embodiments, the first connector 120 is coupled to a conductive periphery structure 302 that extends along a periphery of the pixel array 132. The conductive periphery structure 302 is also coupled to the conductive core 110 of the DTI structure 106 by extending through the first interlayer dielectric 119. In some embodiments, the conductive periphery structure 302 is where the substrate grounding structure (see 130 of FIG. 1B) is in other embodiments, and is level with the grid 206. Using a same layer as the grid 206 reduces the amount of metal layers used to form the integrated device, and reduces the length of the etch used to couple the first connector to the conductive core 110. In embodiments where the first connector 120 is coupled to the conductive periphery structure 302, the etch before forming the connection extends to the top of the conductive periphery structure 302.

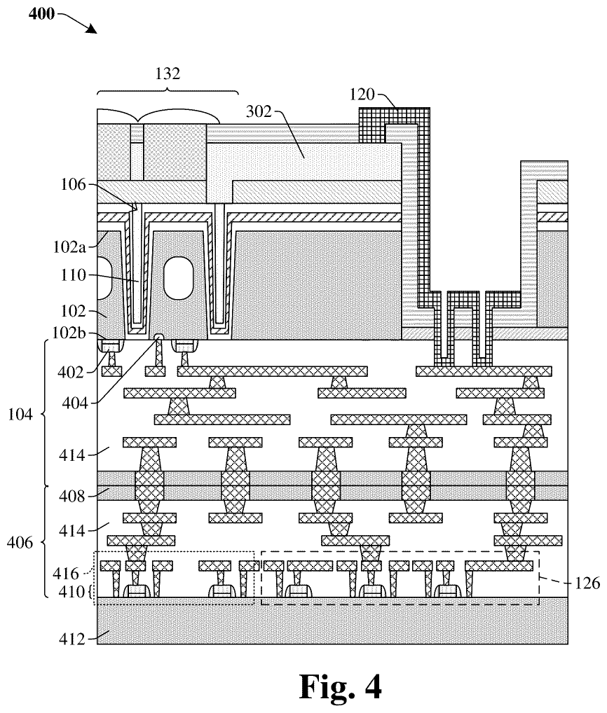

FIG. 4 illustrates a cross-sectional view 400 of some embodiments of a DTI structure with a negatively biased conductive core, where the first connector contacts a periphery structure that is electrically coupled to the conductive core and where the pixel array is in a BCFA configuration.

In some embodiments, the second interlayer dielectric (see 121 of FIG. 1A) is omitted, and the plurality of color filters 202 are level with the grid 206. In further embodiments, the conductive periphery structure 302 couples the first connector 120 to the conductive core 110 of the DTI structure 106. In some embodiments, the DTI structure 106 extends from the first surface 102a to the second surface 102b of the first substrate 102. In other embodiments, the DTI structure 106 extends partially through the first substrate 102 (e.g., through 90% of the substrate, 80% of the substrate, or the like).

FIG. 4 further illustrates the interconnect structure 104 beneath the first substrate 102 in greater detail. Some embodiments comprise the details shown in relation to the interconnect structure 104 beneath the first substrate 102 in FIG. 4 in addition to the features present in FIGS. 1, 2, and 3 level with or above the first substrate 102. A plurality of transfer transistors 402 and floating diffusion nodes 404 are disposed on the second surface 102b of the first substrate 102 within the pixel array 132. In some embodiments, a second interconnect structure 406 is separated from the first interconnect structure 104 by bonding layers 408. The bonding layers 408 couple the first interconnect structure 104 to the second interconnect structure 406. The second interconnect structure 406 is further coupled to a plurality of semiconductor components 410 on a second substrate 412. In some embodiments, the plurality of semiconductor components 410 may comprise transistor devices (e.g., planar FETs, FinFETs, gate-all-around (GAA) devices, etc.). In some embodiments, the level shift circuit (see 126 of FIG. 1A) comprises a portion of the semiconductor components 410 on the second substrate 412. The level shift circuit 126 may further comprise a plurality of semiconductor components within an interlayer dielectric 414 of the first or second interconnect structures 104, 406 (e.g., back end of line (BEOL) devices). In some embodiments, a portion of the semiconductor components 410 may further comprise image processing circuitry and/or pixel circuitry 416 that is part of the pixel array 132.

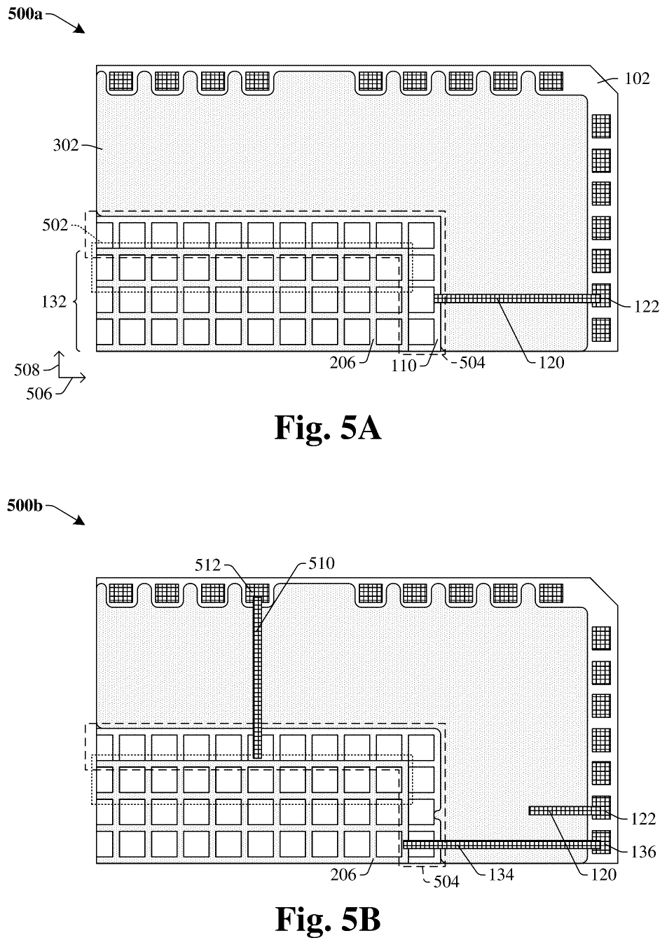

FIGS. 5A-5B illustrate top down views 500a, 500b of some embodiments of a pixel array surrounded by a conductive shield, where the first connector contacts a grid structure above the DTI structure. The metal layers (e.g., the first conductive pad 122, the first connector 120, the conductive core 110, the grid 206, and the conductive periphery structure 302), along with the first substrate 102, are shown, and other layers are omitted to enhance clarity of FIGS. 5A-5B.

As shown in the top down view 500a of FIG. 5A, in some embodiments, the grid 206 does not overly a portion of the DTI structure 106. In some embodiments, a plurality of dummy pixels 504 surround the pixel array 132. In some embodiments, the plurality of dummy pixels extend past outermost pixels of the pixel array 132 in a first direction 506 and a second direction 508 perpendicular to the first direction 506. In some embodiments, the plurality of dummy pixels 504 consist of one or more columns of dummy pixels extending past outermost pixels of the pixel array 132 in the first direction 506 and one or more rows of dummy pixels extending past outermost pixels of the pixel array 132 in the second direction 508.

In some embodiments, a metal blocking layer 502 (shown in phantom) covers a portion of the pixel array. The metal blocking layer 502 covers black level correction (BLC) pixels, mitigating the number of photons the BLC pixels receive. BLC pixels are configured to, during operation, indicate to an image processing the amount of noise or dark current present in the pixel array. The image processing circuit then adjusts the image output taking into account the noise indicated by the BLC pixels (e.g., by reducing the input from other pixels in the pixel array 132 by the input of the BLC pixels). In some embodiments, the metal blocking layer 502 is level with the grid and is in place of the grid 206 above the BLC pixels. In other embodiments, the metal blocking layer 502 is level with the first connector 120 extending over the third interlayer dielectric (123, omitted for clarity), and is formed of a same material as the first connector 120.

As shown in the top down view 500b of FIG. 5B, in some embodiments, the second connector 134 extends from the second pad 136 to contact the grid 206, extending over the conductive core 110 and the third interlayer dielectric (123, omitted for clarity). In some embodiments, the conductive periphery structure 302 extends over and is coupled to the conductive core 110 surrounding the dummy pixels 504, and the first connector 120 is coupled to the conductive periphery structure 302 instead of directly to the conductive core 110. In some embodiments, a third wire 510 extends form a third conductive pad 512 to the metal blocking layer 502, coupling it to a third level shift circuit (not shown), which is configured to bias the metal blocking layer to a third voltage different from the first negative voltage. In other embodiments, the third wire 510 is omitted, and the metal blocking layer 502 is not biased or is coupled to the first connector 120 or second connector 134.

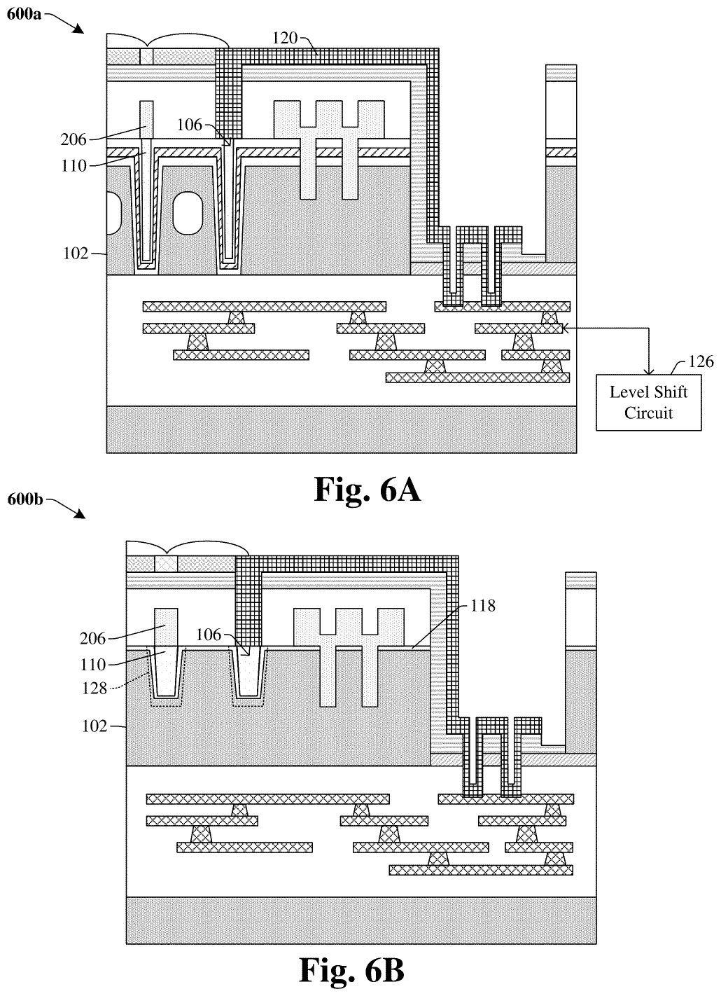

FIGS. 6A-6B illustrate cross-sectional views of some embodiments of a DTI structure with a negatively biased conductive core, where the grid directly contacts the conductive core of the DTI structure.

As shown in the cross-sectional view 600a of FIG. 6A, in some embodiments, the first interlayer dielectric (see 119 of FIG. 1A) is omitted, resulting in lower surfaces of the grid 206 contacting upper surfaces of the conductive core 110. In further embodiments, the first connector 120 directly contacts the conductive core 110 or directly contacts the grid 206, resulting in both the conductive core 110 and the grid 206 being biased by the level shift circuit 126. Biasing both the grid 206 and the conductive core 110 of the DTI structure 106 using one wire (e.g., the first connector 120) simplifies the circuit, and removing the first interlayer dielectric (see 119 of FIG. 1A) reduces the cost of forming the circuit. Additionally, the grid 206 directly contacting the conductive core 110 of the DTI structure 106 removes the gap in isolation introduced by the first interlayer dielectric (see 119 of FIG. 1A), resulting in increased isolation between the pixels and further mitigating cross-talk between the pixels. That is, eliminating the gap between the grid 206 and the conductive core 110 eliminates one path by which photons might travel between the pixels in the pixel array 132.

As shown in the cross-sectional view 600b of FIG. 6B, in some embodiments, the first interlayer dielectric (see 119 of FIG. 1A), the first insulative layer (see 114 of FIG. 1A), and the second insulative layer (see 116 of FIG. 1A) are omitted. In some embodiments, the first and second insulative layers (see 114, 116 of FIG. 1A) comprise high-k materials with intrinsic negative charge, forming a depletion region at the damaged inner sidewalls of the first substrate 102. The introduction of a biased conductive core 110 to the DTI structure 106 forms a larger depletion region at the damaged inner sidewalls. The configuration shown in FIG. 6B results in an embodiment where one insulative barrier layer (e.g., the third insulative layer 118) is effective at isolating the conductive core 110 from the first substrate 102 while the depletion region reduces the dark current and improves white pixel performance to a greater degree than additional barrier layers would have. Further, the separation between the conductive core 110, the grid 206, and the first substrate 102 have decreased, reducing a barrier to the formation of the depletion region and increasing the range of configurable voltages for the level shift circuit (see 126 of FIG. 1A).

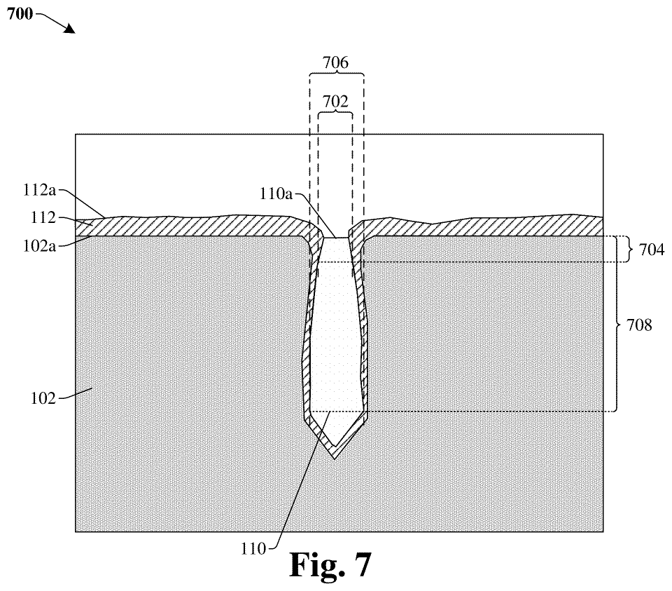

FIG. 7 illustrates a cross-sectional view 700 of a DTI structure with a conductive core before the formation of the grid or the first connector.

The conductive core 110 has a first thickness 702 measured a first distance 704 from the first surface 102a of the first substrate 102, and a second thickness 706 measured a second distance 708 from the first surface 102a of the first substrate 102. In some embodiments, the first thickness 702 is less than the second thickness 706. In some embodiments, the insulative barrier layer 112 has an upper surface 112a extending over the first surface 102a of the first substrate 102, and the conductive core 110 has an upper surface 110a that is recessed from the upper surface of the insulative barrier layer 112.

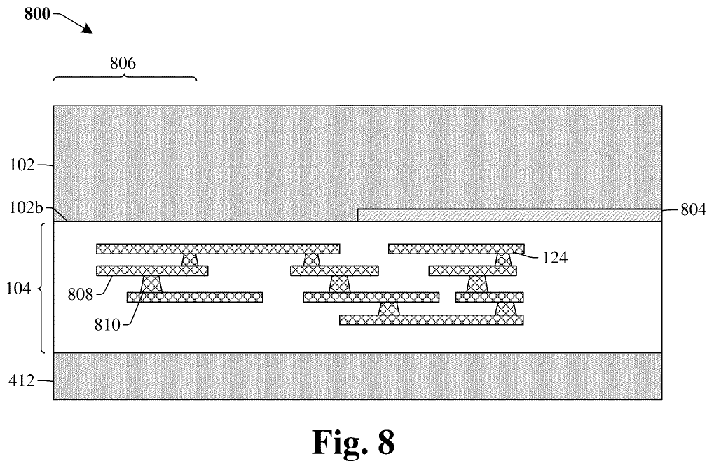

FIGS. 8-24 illustrate a series of cross-sectional views 800-2400 of some embodiments of a method of forming a liquid cooling system with a plurality of openings directing a coolant at specific regions of a semiconductor die using a plurality of valves. Although FIGS. 8-24 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

As shown in the cross-sectional view 800 of FIG. 8, in some embodiments, the interconnect structure 104 is formed on the second surface 102b of the first substrate 102, which is then bonded to a second substrate 412 through one or more bonding layers (see 408 of FIG. 4). In some embodiments, a shallow trench isolation (STI) structure 804 is formed on the second surface 102b of the substrate before the interconnect structure 104 is formed. In some embodiments, a plurality of transfer transistors (see 402 of FIG. 4) and a plurality of floating diffusion nodes (see 404 of FIG. 4) are formed on the second surface 102b of the first substrate 102 within a pixel region 806 of the integrated device. The interconnect structure 104 comprises a plurality of wire levels 808 (comprising the first connector layer 124) and a plurality of via levels 810 coupling the wire levels to one another. The interconnect structure is formed through a plurality of etching steps and a plurality of deposition steps. In some embodiments, the interconnect structure 104 is formed through a plurality of damascene processes, dual damascene processes, or the like. In some embodiments, the first substrate 102 has a thickness measured between the first surface 102a and the second surface 102b between approximately 1 micrometer and 10 micrometers, between approximately 2.5 and 3 micrometers, between approximately 0.75 and 5 micrometers, or another similar range.

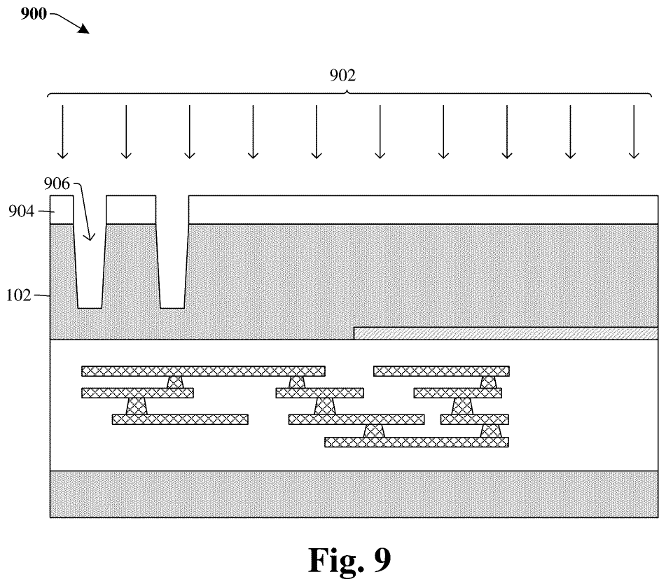

As shown in the cross-sectional view 900 of FIG. 9, a first masking layer 904 is formed over the first substrate 102. In some embodiments, the first masking layer 904 is or comprises a photoresist and is patterned using photolithography. In other embodiments, the first masking layer 904 is a combination of a hard mask (e.g., a silicon nitride (Si₃N₄) hard mask) and a photoresist that is patterned using photolithography. The first masking layer 904 is formed using one or more of physical vapor deposition (PVD), atomic layer deposition (ALD), chemical vapor deposition (CVD), a spin on process, a dipping process, or the like. After the first masking layer 904 is formed and patterned, a first etch 902 is performed on the first substrate 102. In some embodiments, the first etch 902 is an anisotropic dry etching process. The first etch 902 results in a plurality of DTI openings 906 extending into the first substrate 102. The first masking layer 904 is then removed. In some embodiments, the plurality of DTI openings 906 have a depth between approximately 0.5 micrometer and 2 micrometers, between approximately 0.25 and 1.75 micrometers, between approximately 0.75 and 5 micrometers, or another similar range.

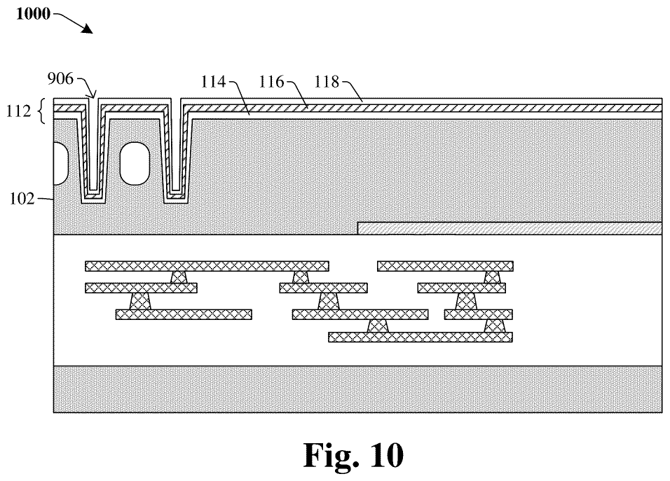

As shown in the cross-sectional view 1000 of FIG. 10, the insulative barrier layer 112 is deposited over the first substrate 102 and into the DTI openings 906. The insulative barrier layer 112 is formed using one or more deposition processes (e.g., PVD, ALD, CVD, or the like). In some embodiments, the insulative barrier layer 112 is or comprises one or more layers of an oxide such as silicon dioxide (SiO₂) or the like, a nitride such as silicon nitride (Si₃N₄) or the like, a high-k dielectric material such as aluminum oxide (Al₂O₃), tantalum oxide (Ta₂O₅), hafnium oxide (HfO₂), hafnium silicon oxide (HfₓSi_{y}O_{z}), hafnium aluminum oxide (HfₓAl_{y}O_{z}), hafnium tantalum oxide (HMO), or the like, or any combination thereof. The insulative barrier layer 112 lines inner sidewalls of the first substrate 102, but does not fill the DTI openings 906.

In some embodiments, the insulative barrier layer 112 comprises one or more of the first insulative layer 114, the second insulative layer 116, and the third insulative layer 118. In some embodiments, the first insulative layer 114 has a thickness between approximately 10 angstroms and 20 angstroms, between approximately 5 angstroms and 15 angstroms, between approximately 12 angstroms and 18 angstroms, or another similar range. In some embodiments, the second insulative barrier layer 116 has a thickness between approximately 60 angstroms and 80 angstroms, between approximately 50 angstroms and 100 angstroms, between approximately 20 angstroms and 75 angstroms, or another similar range. In some embodiments, the third insulative barrier layer 118 has a thickness between approximately 40 angstroms and 100 angstroms, between approximately 60 angstroms and 600 angstroms, between approximately 50 angstroms and 300 angstroms, or another similar range.

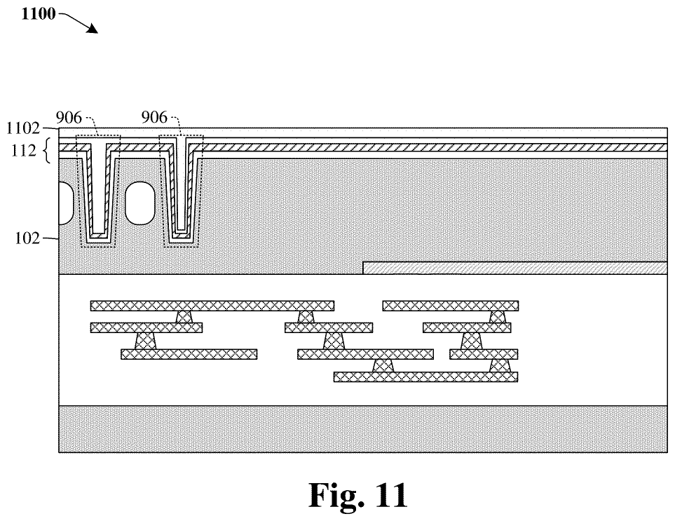

As shown in the cross-sectional view 1100 of FIG. 11, a first conformal conductive layer 1102 is deposited onto the first substrate 102, filling the DTI openings 906. The first conformal conductive layer 1102 is formed using one or more of PVD, ALD, or the like. The first conformal conductive layer 1102 is separated from the first substrate 102 by the insulative barrier layer 112. In some embodiments, the first conformal conductive layer 1102 is or comprises a conductive material, such as one or more of titanium nitride (TiN), an aluminum copper alloy (AlₓCu_{y}), tungsten (W), or the like. In some embodiments, PVD is used to form a first conformal conductive layer 1102 comprising titanium nitride. In other embodiments, ALD is used to form a first conformal conductive layer 1102 comprising tungsten.

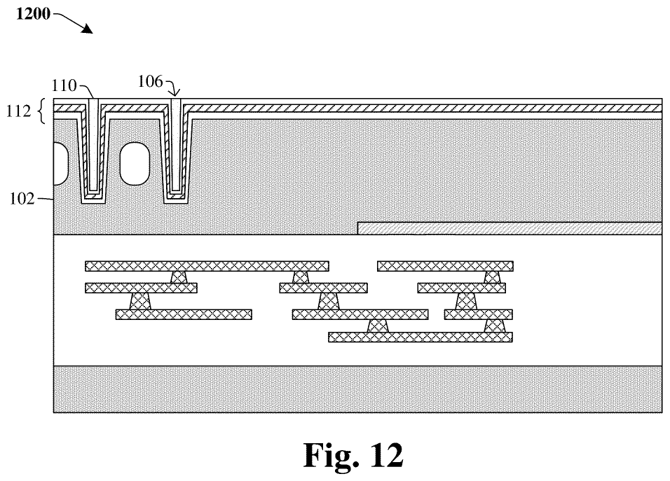

As shown in the cross-sectional view 1200 of FIG. 12, a planarization process (e.g., a chemical mechanical planarization (CMP) process) is used to remove a portion of the first conformal conductive layer (see 1102 of FIG. 11). The planarization process results in portions of the first conformal conductive layer (see 1102 of FIG. 11) above an upper surface of the insulative barrier layer 112 being removed, leaving the conductive core 110 of the DTI structure 106 remaining in the first substrate 102. In some embodiments, the resulting conductive core 110 has an upper surface beneath the upper surface of the insulative barrier layer 112.

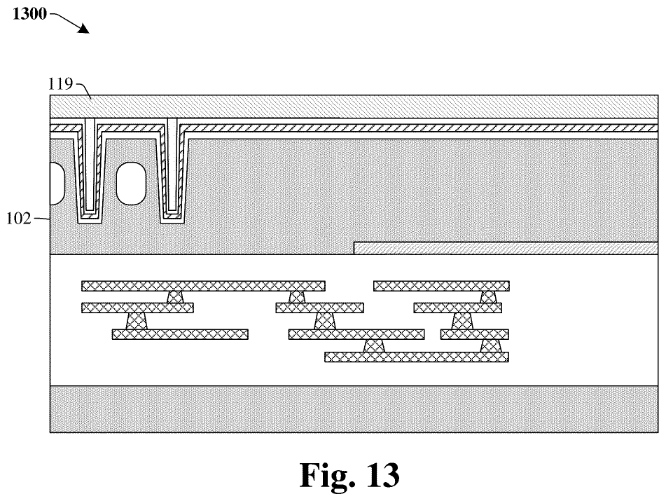

As shown in the cross-sectional view 1300 of FIG. 13, the first interlayer dielectric 119 is deposited over the first substrate 102. In some embodiments, the first interlayer dielectric 119 is or comprises an insulator such as silicon dioxide (SiO₂) or the like. The first interlayer dielectric 119 is formed using one or more deposition processes (e.g., PVD, ALD, CVD, or the like). In some embodiments, the first interlayer dielectric 119 has a thickness between approximately 1000 angstroms and 1500 angstroms, between approximately 1200 angstroms and 1400 angstroms, between approximately 700 angstroms and 1700 angstroms, or another similar range.

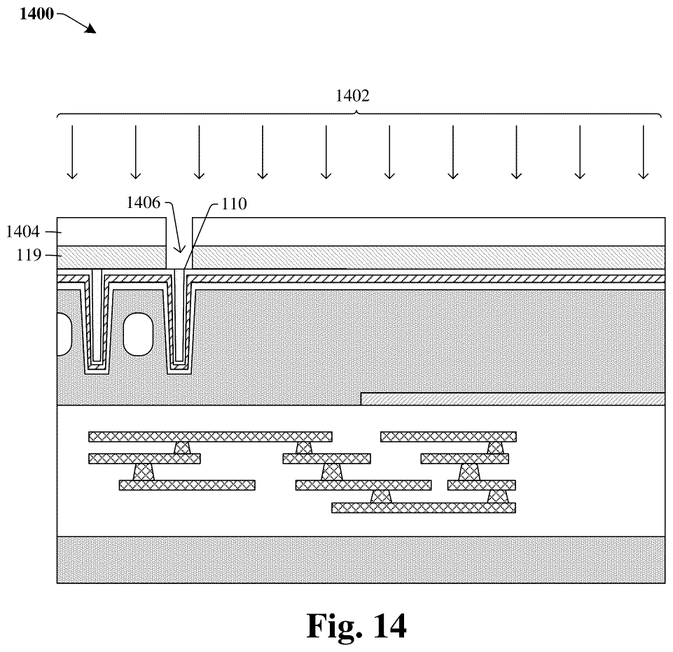

As shown in the cross-sectional view 1400 of FIG. 14, a second masking layer 1404 is formed over the first interlayer dielectric 119. In some embodiments, the second masking layer 1404 is or comprises a photoresist and is patterned using photolithography. In other embodiments, the second masking layer 1404 is a combination of a hard mask (e.g., a silicon nitride (Si₃N₄) hard mask) and a photoresist that is patterned using photolithography. The second masking layer 1404 is formed using one or more of PVD, ALD, CVD, a spin on process, a dipping process, or the like. After the second masking layer 1404 is formed and patterned, a second etch 1402 is performed on the first interlayer dielectric 119. In some embodiments, the second etch 1402 is an anisotropic dry etching process. The second etch 1402 results in one or more DTI contact openings 1406 extending through the first interlayer dielectric 119 and exposing the conductive core 110. The second masking layer 1404 is then removed.

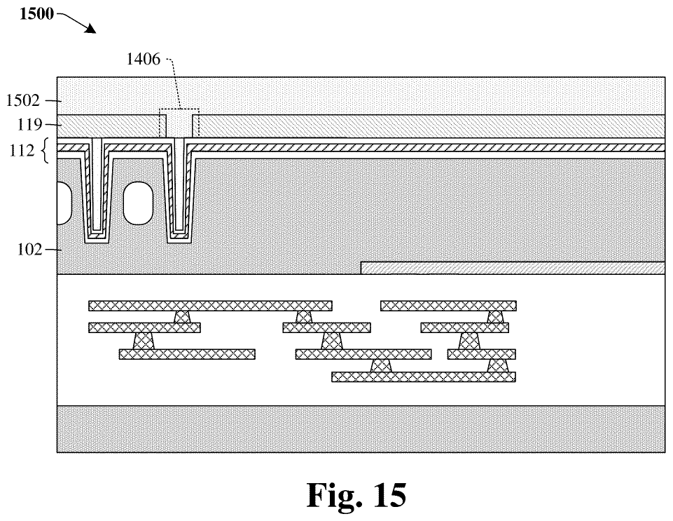

As shown in the cross-sectional view 1500 of FIG. 15, the second conformal conductive layer 1502 is deposited over the first substrate 102 and into the DTI contact openings 1406. The second conformal conductive layer 1502 is formed using one or more of PVD, ALD, or the like. The second conformal conductive layer 1502 is separated from the first substrate 102 by the insulative barrier layer 112 and the first interlayer dielectric 119. In some embodiments, the second conformal conductive layer 1502 is or comprises a conductive material, such as one or more of titanium nitride (TiN), an aluminum copper alloy (AlₓCu_{y}), tungsten (W), or the like. In some embodiments, the second conformal conductive layer 1502 has a thickness between approximately 200 angstroms and 2500 angstroms, between approximately 250 angstroms and 400 angstroms, between approximately 300 angstroms and 2000 angstroms, or another similar range. In some embodiments, the thickness of the second conformal conductive layer 1502 is different depending on the material used. For example, in embodiments with a tungsten second conformal conductive layer 1502, the second conformal conductive layer 1502 may have a thickness equal to or greater than 2000 angstroms. In embodiments with an aluminum copper alloy second conformal conductive layer 1502, the second conformal conductive layer 1502 may have a thickness of less than 500 angstroms.

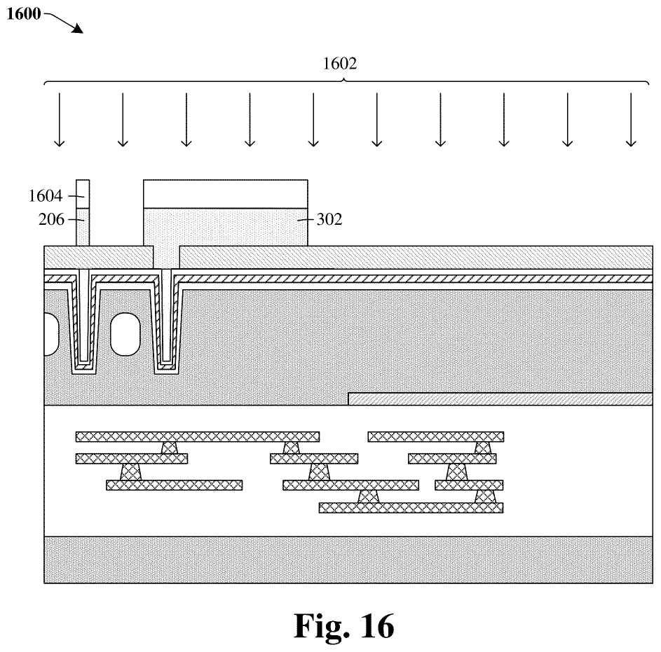

As shown in the cross-sectional view 1600 of FIG. 16, a third masking layer 1604 is formed over the first substrate 102. In some embodiments, the third masking layer 1604 is or comprises a photoresist and is patterned using photolithography. The third masking layer 1604 is formed using one or more of PVD, ALD, CVD, a spin on process, a dipping process, or the like. After the third masking layer 1604 is formed and patterned, a third etch 1602 is performed on the second conformal conductive layer (see 1502 of FIG. 15). In some embodiments, the third etch 1602 is an anisotropic dry etching process. The third etch 1602 results in the second conformal conductive layer (see 1502 of FIG. 15) being patterned into the grid 206 and the conductive periphery structure 302. In some embodiments, the grid 206 is mechanically coupled to the conductive periphery structure 302. The third masking layer 1604 is then removed.

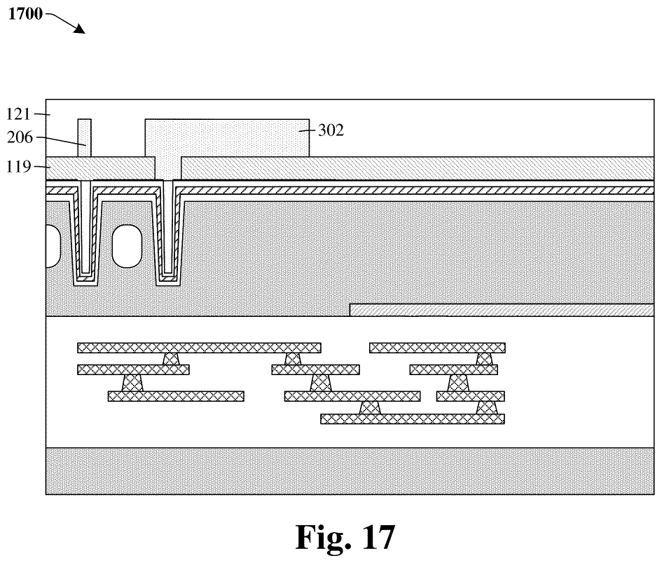

As shown in the cross-sectional view 1700 of FIG. 17, the second interlayer dielectric 121 is deposited over the first interlayer dielectric 119 and surrounding the grid 206 and the conductive periphery structure 302. In some embodiments, the second interlayer dielectric 121is or comprises an insulator such as silicon dioxide (SiO₂), a low deposited rate protective oxide (LRPO), or the like. In some embodiments, the second interlayer dielectric 121 is or comprises a same material as the first interlayer dielectric 119. The second interlayer dielectric 121 is formed using one or more deposition processes (e.g., PVD, ALD, CVD, or the like). In some embodiments, the second interlayer dielectric 121 has a thickness overlying the conductive periphery structure 302 between approximately 1500 angstroms and 2000 angstroms, between approximately 1600 angstroms and 1800 angstroms, between approximately 1500 angstroms and 1800 angstroms, or another similar range.

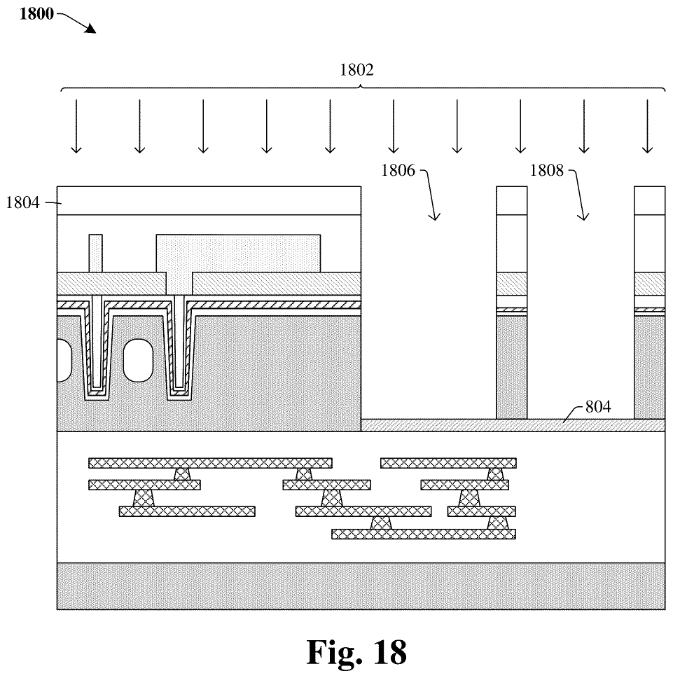

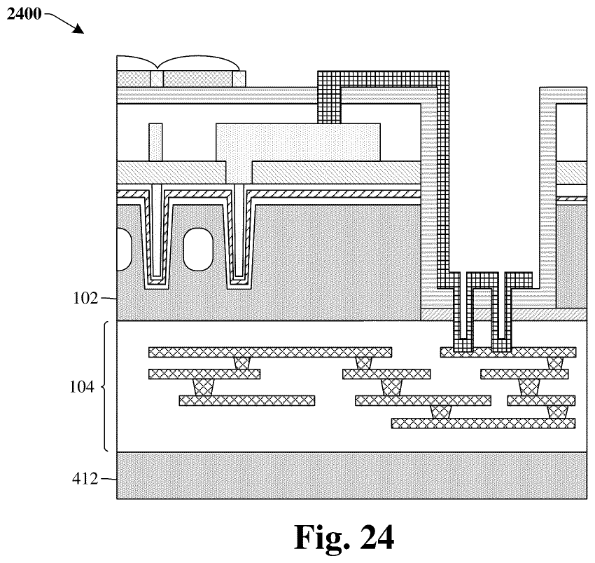

As shown in the cross-sectional view 1800 of FIG. 18, a fourth masking layer 1804 is formed over the second interlayer dielectric 121. In some embodiments, the fourth masking layer 1804 is or comprises a photoresist and is patterned using photolithography. The fourth masking layer 1804 is formed using one or more of PVD, ALD, CVD, a spin on process, a dipping process, or the like. After the fourth masking layer 1804 is formed and patterned, a fourth etch 1802 is performed on the second interlayer dielectric 121, the first interlayer dielectric 119, and the first substrate 102. In some embodiments, the fourth etch 1802 is an anisotropic dry etching process. The fourth etch 1802 results in scribe line openings 1808 and conductive pad openings 1806 being formed, and the STI structure 804 being exposed. In some embodiments, the scribe line openings 1808 are omitted, and a method of wafer dicing that does not utilize scribe lines is performed (see FIG. 24). The fourth masking layer 1804 is then removed.

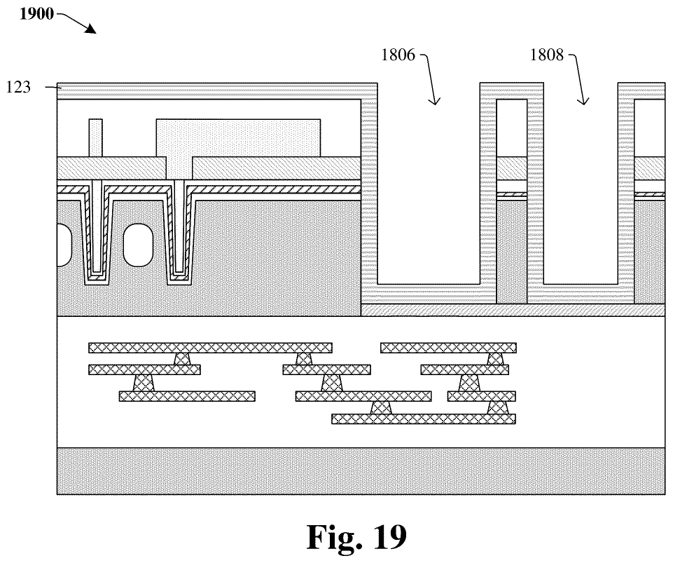

As shown in the cross-sectional view 1900 of FIG. 19, the third interlayer dielectric 123 is deposited over the second interlayer dielectric 121 and into the scribe line openings 1808 and the conductive pad openings 1806. In some embodiments, the third interlayer dielectric 123 is or comprises an insulator such as silicon dioxide (SiO₂) or the like. In some embodiments, the third interlayer dielectric 123 is or comprises a same material as the first interlayer dielectric 119. The third interlayer dielectric 123 is formed using one or more deposition processes (e.g., PVD, ALD, CVD, or the like).

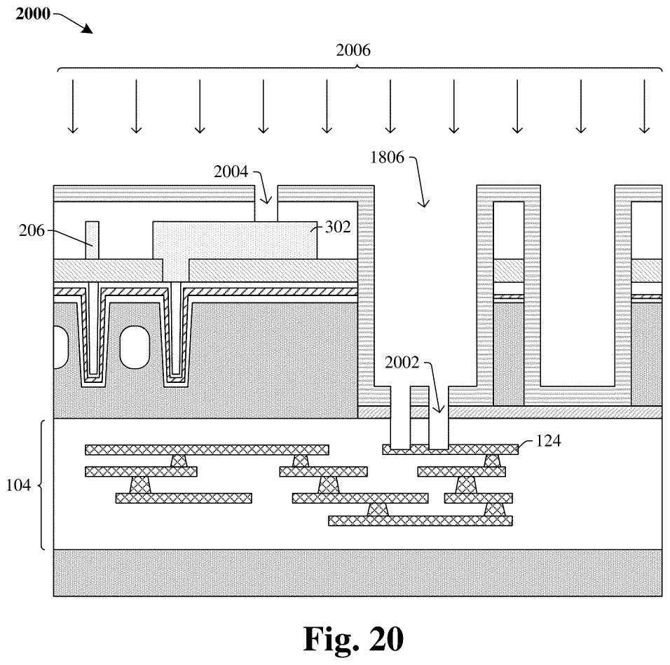

As shown in the cross-sectional view 2000 of FIG. 20, one or more etching processes 2006 are performed. In some embodiments, the one or more etching processes 2006 are anisotropic dry etching processes. The one or more etching processes 2006 result in pad contact openings 2002 at a bottom surface of the conductive pad openings 1806, exposing a first connector layer 124 of the interconnect structure 104. The one or more etching processes 2006 further result in a conductive wire opening 2004 exposing the conductive periphery structure 302. In some embodiments, the one or more etching processes 2006 further result in forming one or more grid contact openings (not shown) that expose the grid 206. In some embodiments, one or more masking layers (not shown) are used to pattern the conductive pad openings 1806 and the conductive wire opening 2004. In some embodiments, the conductive pad openings 1806 and the conductive wire opening 2004 are forming during a single etching step using a single mask.

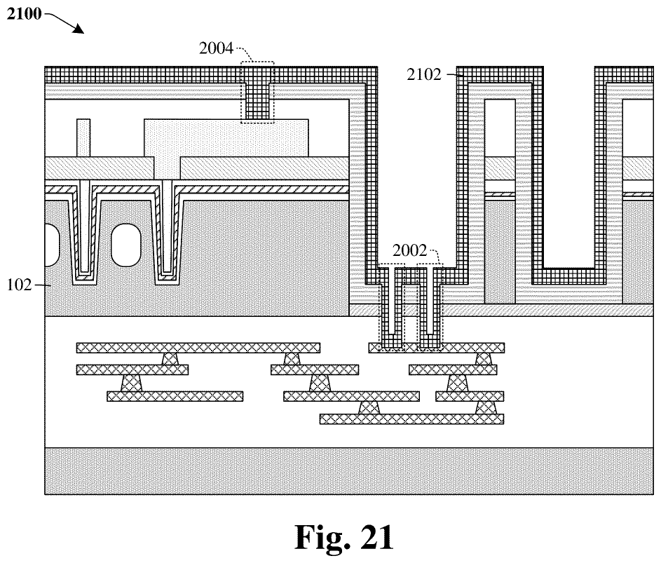

As shown in the cross-sectional view 2100 of FIG. 21, a third conformal conductive layer 2102 is deposited over the first substrate 102 and into the conductive pad openings 1806 and the conductive wire opening 2004. The third conformal conductive layer 2102 is formed using one or more of PVD, ALD, or the like. In some embodiments, the third conformal conductive layer 2102 is or comprises a conductive material, such as one or more of titanium nitride (TiN), an aluminum copper alloy (AlₓCu_{y}), tungsten (W), or the like. In some embodiments, the third conformal conductive layer 2102 has a thickness between approximately 10000 angstroms and 15000 angstroms, between approximately 11000 angstroms and 13000 angstroms, between approximately 11500 angstroms and 12500 angstroms, or another similar range.

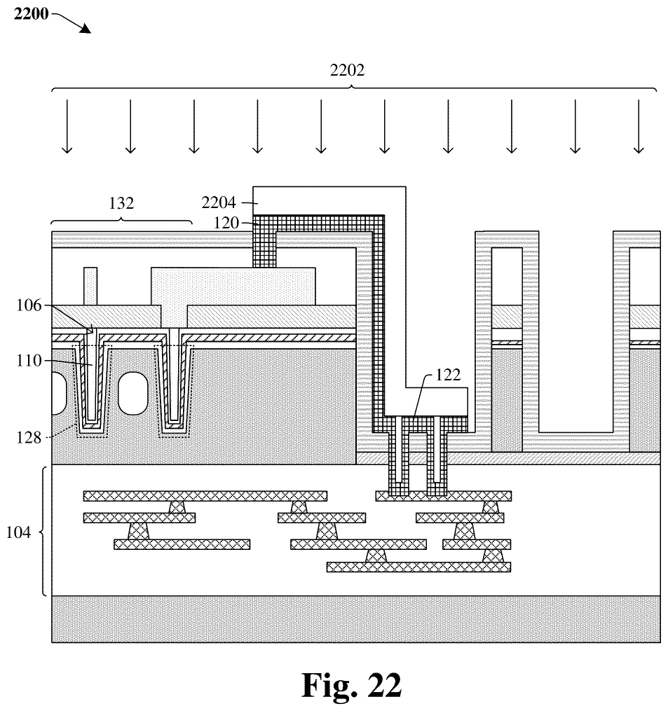

As shown in the cross-sectional view 2200 of FIG. 22, a fifth masking layer 2204 is formed over the third conformal conductive layer (see 2102 of FIG. 21). In some embodiments, the fifth masking layer 2204 is or comprises a photoresist and is patterned using photolithography. The fifth masking layer 2204 is formed using one or more of PVD, ALD, CVD, a spin on process, a dipping process, or the like. After the fifth masking layer 2204 is formed and patterned, a fifth etch 2202 is performed on the second conformal conductive layer (see 1502 of FIG. 15). In some embodiments, the fifth etch 2202 is an anisotropic dry etching process. The fifth etch 2202 removes portions of the third conformal conductive layer (see 2102 of FIG. 21), resulting in the first connector 120 and the first conductive pad 122 remaining. The fifth masking layer 2204 is then removed.

The first connector 120 and the first conductive pad 122 couple the conductive core 110 of the DTI structure 106 to the level shift circuit (see 126 of FIG. 1A) within the interconnect structure 104. During operation, the level shift circuit (see 126 of FIG. 1A) may bias the conductive core through the aforementioned coupling, resulting in a depletion region 128 forming around the DTI structure 106. The depletion region 128 isolates the operation of the pixels in the pixel array 132 from the damaged inner sidewalls of the first substrate 102, thereby reducing white noise resulting from variations in the output signal caused by the damaged inner sidewalls.

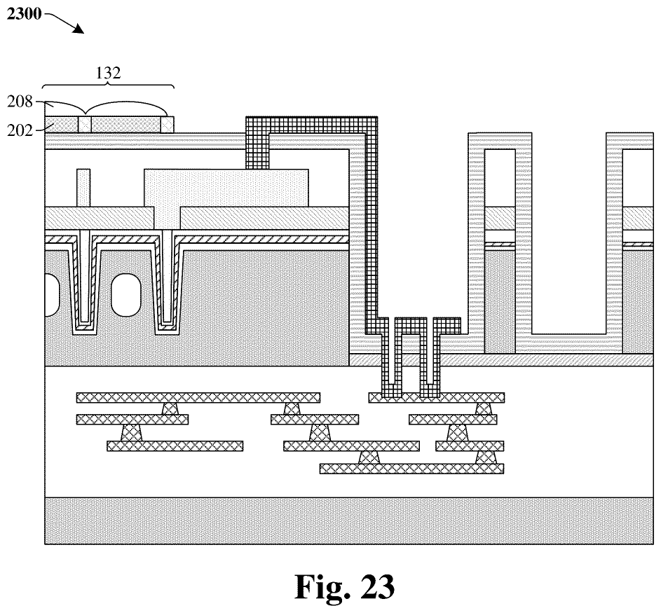

As shown in the cross-sectional view 2300 of FIG. 23, the plurality of color filters 202 and the plurality of lenses 208 are formed over the pixels of the pixel array 132. The plurality of color filters 202 comprise filters of different colors (e.g., red, blue, and green filters) that are separated in a grid pattern from one another. The plurality of color filters 202 are formed using multiple deposition processes and masks, where each color of filter is formed separately. The plurality of lenses 208 are subsequently formed overlying the plurality of color filters 202.

As shown in the cross-sectional view 2400 of FIG. 24, a portion of the first substrate 102, the second substrate 412, and the interconnect structure 104 beneath the scribe line openings 1808 are removed, separating the second substrate 412 into a plurality of dies. In some embodiments, the plurality of dies are separated using laser cutting, mechanical sawing, a scribe and break process, or the like. The plurality of dies are no longer physically coupled to one another. In some embodiments, a portion of the plurality of dies comprise application specific integrated circuits (ASICs).

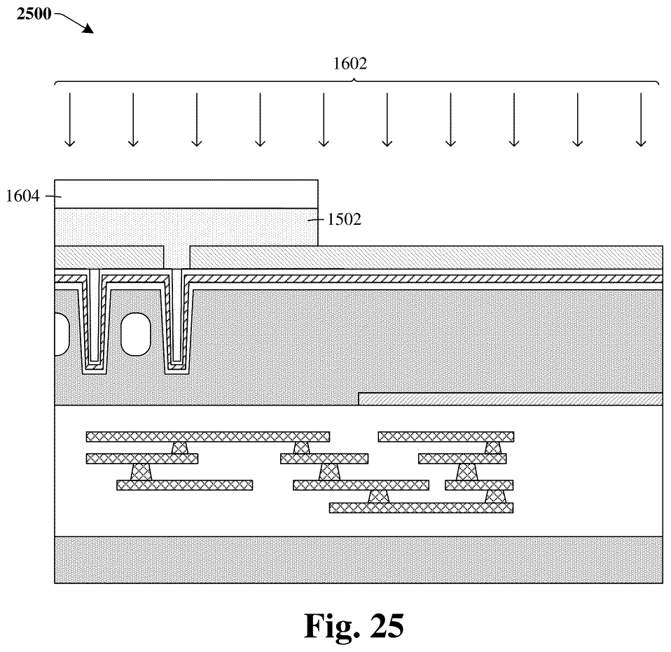

FIGS. 25-27 illustrate a series of cross-sectional views 2500-2700 of some alternative embodiments of method steps of forming a liquid cooling system with a plurality of openings directing a coolant at specific regions of a semiconductor die using a plurality of valves. Although FIGS. 25-27 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

As shown in the cross-sectional view 2500 of FIG. 25, as an alternative to the method step shown in FIG. 16, in some embodiments, the third masking layer 1604 covers portions of the second conformal conductive layer 1502 that correspond to the grid (see 206 of FIG. 16) and openings between the segments of the grid (see 206 of FIG. 16). This results in an outer sidewall of the conductive periphery structure (see 302 of FIG. 16) being etched by the third etch 1602. In some embodiments, a gap between the conductive periphery structure (see 302 of FIG. 16) and the portions of the second conformal conductive layer 1502 that correspond to the grid (see 206 of FIG. 16) is also etched, electrically isolating the conductive periphery structure (see 302 of FIG. 16) from the grid (see 206 of FIG. 16) to be formed hereafter.

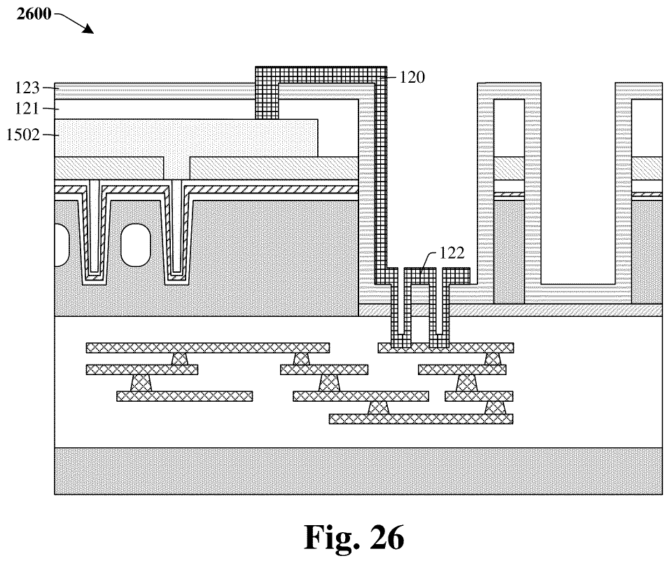

In other embodiments, the third masking layer 1604 and the third etch 1602 are omitted, and the second conformal conductive layer 1502 is etched by the fourth etch (see 1802 of FIG. 18) to have outer sidewalls surrounding the conductive pad openings 1806. The grid (see 206 of FIG. 2) is later etched as described below in relation to FIG. 26. This results in the alternative method having a same amount of masking layers used during fabrication of the integrated device, thereby incurring no additional cost through additional masking layers and photolithography processes.

As shown in the cross-sectional view 2600 of FIG. 26, in embodiments of the method flow where the grid (see 206 of FIG. 16) is not etched before the formation of the second interlayer dielectric 121, steps corresponding to the steps shown in FIGS. 17-22 result in the first connector 120 contacting the first conductive pad 122 and a remaining portion of the second conformal conductive layer 1502. In some embodiments, the second interlayer dielectric 121 is omitted, such that the third interlayer dielectric 123 directly contacts and covers an upper surface of the second conformal conductive layer 1502.

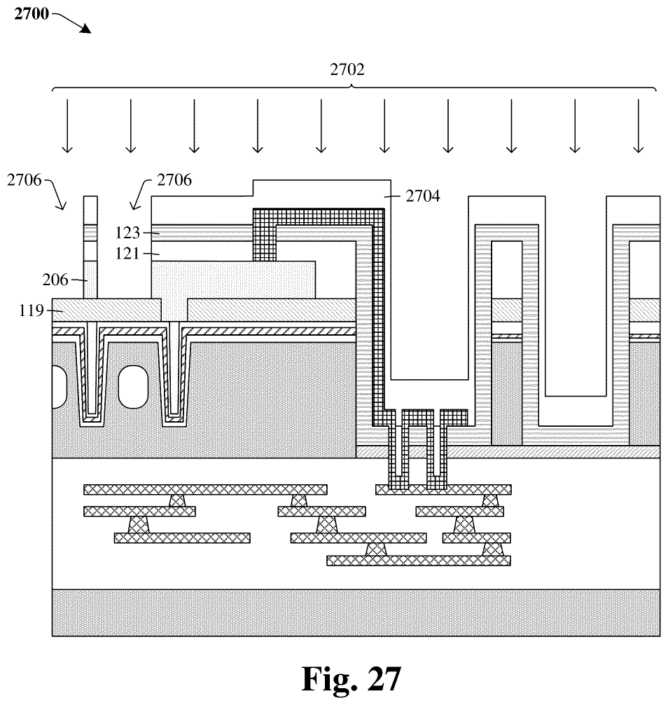

As shown in the cross-sectional view 2700 of FIG. 27, continuing from the embodiment shown in FIG. 26, the second conformal conductive layer (see 1502 of FIG. 26) is patterned using a sixth etching step 2702 according to a sixth masking layer 2704. The sixth etching step 2702 results in the etching of the grid 206 as well as the removal of portions of the second interlayer dielectric 121 and portions of the third interlayer dielectric 123, forming color filter openings 2706 and exposing the grid 206 and the first interlayer dielectric 119.

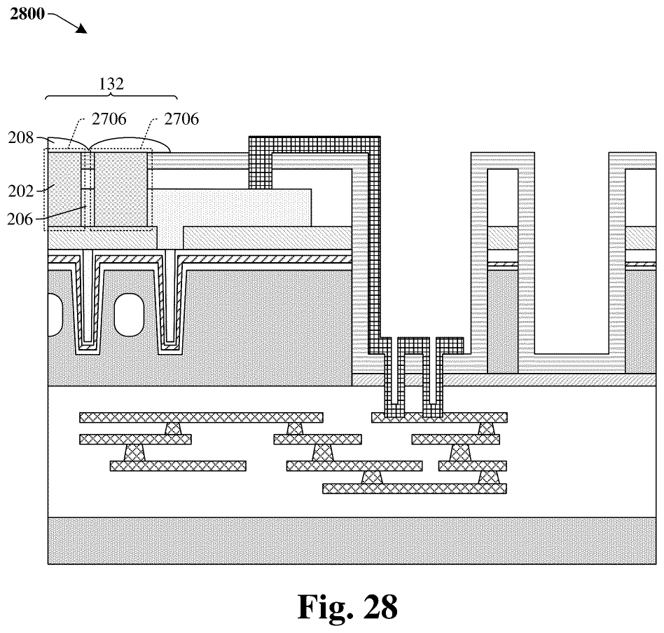

As shown in the cross-sectional view 2800 of FIG. 28, color filters 202 are formed within the color filter openings 2706 and level with the grid 206. Further, in some embodiments, the plurality of lenses 208 are formed over the color filters 202, such that the plurality of lenses are centered on the pixels of the pixel array 132. The alternative method step shown in FIGS. 25-28 used to form the pixel array 132 result in the color filters 202 being a buried color filter array (BCFA).

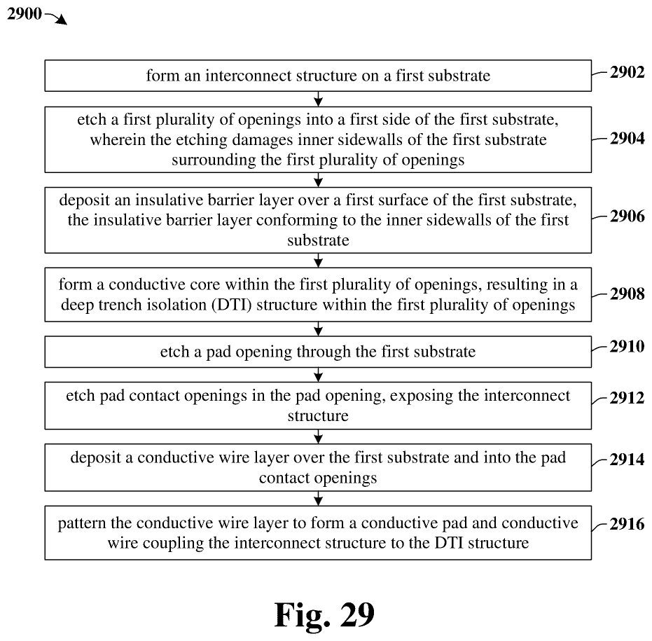

FIG. 29 illustrates a flowchart 2900 of some embodiments of a method of forming a DTI structure with a negatively biased conductive core. Although this method and other methods illustrated and/or described herein are illustrated as a series of acts or events, it will be appreciated that the present disclosure is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At 2902, an interconnect structure is formed on a first substrate. An example of a drawing illustrating this step can be found, for example, in FIG. 8.

At 2904, a first plurality of openings are etched into a first side of the first substrate, wherein the etching damages inner sidewalls of the first substrate surrounding the first plurality of openings. An example of a drawing illustrating this step can be found, for example, in FIG. 9.

At 2906, an insulative barrier layer is deposited over a first surface of the first substrate, the insulative barrier layer conforming to outer sidewalls of the openings. An example of a drawing illustrating this step can be found, for example, in FIG. 10.

At 2908, a conductive core is formed within the first plurality of openings, resulting in a deep trench isolation (DTI) structure within the first plurality of openings. An example of a drawing illustrating this step can be found, for example, in FIGS. 11-12.

At 2910, a pad opening is etched through the first substrate. An example of a drawing illustrating this step can be found, for example, in FIG. 18.

At 2912, pad contact openings are etched in the pad opening, exposing the interconnect structure. An example of a drawing illustrating this step can be found, for example, in FIG. 20.

At 2914, a conductive wire layer is deposited over the first substrate and into the pad contact openings. An example of a drawing illustrating this step can be found, for example, in FIG. 21.

At 2916, the conductive wire layer is patterned to form a conductive pad and conductive wire coupling the interconnect structure to the DTI structure. An example of a drawing illustrating this step can be found, for example, in FIG. 22.

Some embodiments relate to an integrated device including: a first substrate having a first side and a second side; a pixel array on the first side of the first substrate; a deep trench isolation (DTI) structure surrounding photodiodes of the pixel array, the DTI structure comprising an insulative barrier layer surrounding a conductive core; an interconnect structure on the second side of the first substrate; a conductive pad level with the second side of the first substrate coupled to the interconnect structure; and a first connector coupling the conductive pad to the conductive core of the DTI structure and extending along the first side of the first substrate.

Other embodiments relate to an integrated device including: a first substrate comprising a first side and a second side; an interconnect structure on the second side of the first substrate; a level shift circuit on a second substrate coupled to the interconnect structure; a deep trench isolation (DTI) structure on a first side of the first substrate; and a first connector coupling the DTI structure to the level shift circuit through the interconnect structure.

Yet other embodiments relate to a method of forming an integrated device, including: forming an interconnect structure on a first substrate; etching a first plurality of openings into a first side of the first substrate, where the etching damages inner sidewalls of the first substrate surrounding the first plurality of openings; depositing an insulative barrier layer over the first surface of the first substrate, the insulative barrier layer conforming to outer sidewalls of the openings; forming a conductive core within the first plurality of openings, resulting in a deep trench isolation (DTI) structure within the first plurality of openings; etching a pad opening through the first substrate; etching pad contact openings in the pad opening, exposing the interconnect structure; depositing a conductive wire layer over the first substrate and into the pad contact openings; and patterning the conductive wire layer to form a conductive pad and conductive wire coupling the interconnect structure to the DTI structure.

It will be appreciated that in this written description, as well as in the claims below, the terms “first”, “second”, “second”, “third” etc. are merely generic identifiers used for ease of description to distinguish between different elements of a figure or a series of figures. In and of themselves, these terms do not imply any temporal ordering or structural proximity for these elements, and are not intended to be descriptive of corresponding elements in different illustrated embodiments and/or un-illustrated embodiments. For example, “a first dielectric layer” described in connection with a first figure may not necessarily correspond to a “first dielectric layer” described in connection with another figure, and may not necessarily correspond to a “first dielectric layer” in an un-illustrated embodiment.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated device, comprising:
a substrate having a first side and a second side;
a pixel array on the first side of the substrate;
a deep trench isolation (DTI) structure surrounding photodiodes of the pixel array, the DTI structure comprising an insulative barrier layer surrounding a conductive core;
an interconnect structure on the second side of the substrate;
a conductive pad level with the second side of the substrate coupled to the interconnect structure; and
a first connector coupling the conductive pad to the conductive core of the DTI structure and extending along the first side of the substrate.

2. The integrated device of claim 1, further comprising a grid layer overlying the DTI structure, wherein the grid layer comprises a grid that has a grid pattern extending across the first side of the substrate directly over the DTI structure.

3. The integrated device of claim 2, wherein the first connector is coupled to the conductive core of the DTI structure through the grid.

4. The integrated device of claim 2, wherein the first connector is directly coupled to the conductive core of the DTI structure and extends through the grid layer.

5. The integrated device of claim 2, wherein the grid layer further comprises a substrate grounding structure extending around a periphery of the grid, wherein the substrate grounding structure comprises one or more prongs extending into the substrate.

6. The integrated device of claim 2, wherein the grid layer comprises a conductive shield that extends between the DTI structure and the conductive pad, wherein the conductive shield is level with the grid and is separated from the substrate by the insulative barrier layer.

7. The integrated device of claim 2, wherein the grid has a lower surface directly contacting and covering an upper surface of the DTI structure.

8. The integrated device of claim 1, wherein the DTI structure further comprises a second insulative barrier layer and a third insulative barrier layer.

9. An integrated device, comprising:
a first substrate comprising a first side and a second side;
an interconnect structure on the second side of the first substrate;
a level shift circuit on a second substrate coupled to the interconnect structure;
a deep trench isolation (DTI) structure on the first side of the first substrate; and
a first connector coupling the DTI structure to the level shift circuit through the interconnect structure.

10. The integrated device of claim 9, wherein the first connector comprises an aluminum copper alloy and the DTI structure comprises a conductive core comprising tungsten.

11. The integrated device of claim 9, wherein the DTI structure comprises a conductive core and an insulative barrier layer separating the conductive core from the DTI structure.

12. The integrated device of claim 11, wherein the insulative barrier layer comprises a first insulative barrier layer contacting both the first substrate and the conductive core.

13. The integrated device of claim 12, wherein the insulative barrier layer comprises a first insulative layer, a second insulative layer, and a third insulative layer, wherein the first insulative layer contacts the first substrate and comprises a high-k material.

14. A method of forming an integrated device, comprising:
forming an interconnect structure on a first substrate;
etching a first plurality of openings into a first side of the first substrate, wherein inner sidewalls of the first substrate surround the first plurality of openings;
depositing an insulative barrier layer over a first surface of the first substrate, the insulative barrier layer conforming to the inner sidewalls of the first substrate;
forming a conductive core within the first plurality of openings, resulting in a deep trench isolation (DTI) structure within the first plurality of openings;
etching a pad opening through the first substrate;
etching pad contact openings in the pad opening, exposing the interconnect structure;
depositing a conductive wire layer over the first substrate and into the pad contact openings; and
patterning the conductive wire layer to form a conductive pad and conductive wire coupling the interconnect structure to the DTI structure.

15. The method of claim 14, further comprising etching a DTI contact opening over the DTI structure before depositing the conductive wire layer, whereby the conductive wire is coupled directly to the DTI structure.

16. The method of claim 14, further comprising:
depositing a conformal conductive layer over the DTI structure and the first substrate after forming the conductive core; and
patterning the conformal conductive layer to form a grid, wherein the DTI structure and the grid comprise a plurality of segments forming a grid pattern, and wherein the plurality of segments of the grid are over and aligned with the plurality of segments of the DTI structure.

17. The method of claim 16, wherein the patterning of the conformal conductive layer also forms a substrate grounding structure surrounding a periphery of the DTI structure.

18. The method of claim 16, further comprising etching a grid contact opening over the grid before depositing the conductive wire layer, whereby the conductive wire is coupled to the grid.

19. The method of claim 16, further comprising forming a first interlayer dielectric before forming the conformal conductive layer, wherein the grid is spaced from the DTI structure by the first interlayer dielectric.

20. The method of claim 16, wherein the conformal conductive layer is deposited onto the conductive core, resulting in a lower surface of the grid contacting an upper surface of the conductive core.
